(19) United States
(12) Patent Application Publication
(10) Pub. No.: US 2010/0244969 A1
(43) Pub. Date: Sep. 30, 2010

(54) TEMPERATURE COMPENSATED OSCILLATION CIRCUITS

(75) Inventors: Ming-Da Tsai, Miaoli County (TW); Ling-Wei Ke, Hsinchu County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/413,687

(22) Filed: Mar. 30, 2009

(51) Int. Cl. H03L 1/02

(52) U.S. Cl. 331/66

(57) ABSTRACT

A temperature compensated oscillation circuit capable of providing a stable frequency output over temperature is provided, in which an oscillator with a crystal resonator is arranged to generate an oscillation signal with an output frequency, and a temperature sensor provides a temperature compensation voltage of which a function is linear with respect to an ambient temperature of the oscillator. A first accumulation mode MOS varactor is coupled to the oscillator, and the first accumulation mode MOS varactor adjusts a capacitance thereof in response to the temperature compensation voltage, such that the coupled oscillator has a frequency compensation over temperature for the oscillation signal, wherein the frequency compensation substantially varies as an inverse function of a deviation of the crystal resonator over temperature when the ambient temperature is within a predetermined temperature range.

### BACKGROUND OF THE INVENTION

1. Field of the Invention

The invention relates to oscillation circuits, and more particularly, to an oscillation circuit capable of compensating frequency offset (deviation) caused by ambient temperature.

2. Description of the Related Art

A crystal oscillator generates a signal for a clock, wherein the signal is input to a clock generator which in turn generates a clock signal necessary for driving an electronic element. In recent years, crystal oscillators have been popularly used to provide a reference frequency signal for radio communication, such as devices or telephone sets for portable, mobile and cordless telephone systems. Crystal oscillators, however, provide about a 5 parts per million (ppm) frequency stability over temperature, as shown in FIG. 1. Generally, the frequency offset over temperature is caused by a crystal resonator of the crystal oscillator. Thus, it is desirable to compensate for frequency offset (deviation), so that a stable frequency output over temperature could be provided.

### BRIEF SUMMARY OF THE INVENTION

Embodiments of a temperature compensated oscillation circuit are provided, in which an oscillator with a crystal resonator is arranged to generate an oscillation signal with an output frequency, and a temperature sensor is arranged to provide a temperature compensation voltage of which a function is linear with respect to an ambient temperature of the oscillator. A first accumulation mode MOS varactor is coupled to the oscillator, and the first accumulation mode varactor is arranged to adjust a capacitance thereof in response to the temperature compensation voltage, such that the coupled oscillator has a frequency compensation over temperature for the oscillation signal, wherein the frequency compensation substantially varies as an inverse function of a deviation of the crystal resonator over temperature when the ambient temperature is within a predetermined temperature range.

The invention provides another embodiment of a temperature compensated oscillation circuit, in which a crystal oscillator is arranged to provide an oscillation signal with an output frequency, and a temperature sensor is arranged to detect an ambient temperature of the crystal oscillator and provide a temperature compensation voltage which is linear with respect to a detected ambient temperature. A first accumulation mode MOS varactor is coupled to the crystal oscillator, and the first accumulation mode MOS varactor is arranged to receive the temperature compensation voltage provided by the temperature sensor to compensate the output frequency of the oscillation signal when the detected ambient temperature is within a predetermined temperature range.

The invention provides an embodiment of a method for compensating frequency offset over temperature of a crystal oscillator, in which an ambient temperature of an oscillator having a crystal resonator is detected to provide a temperature compensation voltage of which a function is linear with respect to the detected ambient temperature. The temperature compensation voltage is applied to a first accumulation mode MOS varactor coupled to the oscillator to adjust a capacitance provided by the first accumulation mode MOS varactor, such that the oscillator has a frequency compensation over temperature for the oscillation signal, wherein the frequency compensation substantially varies over temperature as an inverse function of a deviation of the crystal resonator over temperature when the detected ambient temperature is within a predetermined temperature range.

### BRIEF DESCRIPTION OF THE DRAWINGS

The invention can be more fully understood by reading the subsequent detailed description and examples with references made to the accompanying drawings, wherein:

FIG. 1 shows a relationship between frequency offset of a crystal resonator in a crystal oscillator and temperature;

FIG. 2 is a schematic diagram of a temperature compensated oscillation circuit;

FIG. 3 shows a relationship between temperature and the temperature detection voltage;

FIG. 4 shows a diagram of an accumulation mode MOS varactor;

FIG. 5 shows a component symbol of the accumulation mode MOS varactor shown in FIG. 4;

FIG. 6 shows a relationship between the gate-source voltage and capacitance of the accumulation mode MOS varactor;

FIG. 7 shows a relationship between temperature and capacitance provided by the voltage to capacitance circuit;

FIG. 8 shows a relationship between the output frequency of the crystal oscillator and temperature;

FIG. 9 shows an embodiment of the temperature compensated oscillation circuit;

FIG. 10 shows another embodiment of the temperature compensated oscillation circuit;

FIG. 11 shows a relationship between the capacitance provided by the voltage to capacitance circuit and temperature;

FIG. 12 shows a relationship between the capacitance provided by the voltage to capacitance circuit and temperature; and

FIG. 13 shows a relationship between the output frequency of the crystal oscillator and temperature.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The following description is of the best-contemplated mode of carrying out the invention. This description is made for the purpose of illustrating the general principles of the invention and should not be taken in a limiting sense. The scope of the invention is best determined by reference to the appended claims.

To compensate for frequency offset (deviation) caused by ambient temperature, embodiments of the invention pre-adjust an output frequency of a crystal oscillator over the temperature, so that the crystal oscillator has a frequency compensation over temperature for the oscillation signal, thereby offsetting the frequency deviation. Accordingly, the frequency deviation can be compensated by the frequency compensation such that the output frequency of the oscillation signal is substantially independent from temperature. As such, a stable frequency output of the oscillation circuit over temperature can be provided. For example, embodiments of the invention pre-adjust the output frequency of the crystal oscillator such that frequency compensation substantially varies as an inverse function of a deviation of a crystal resonator in the crystal oscillator.

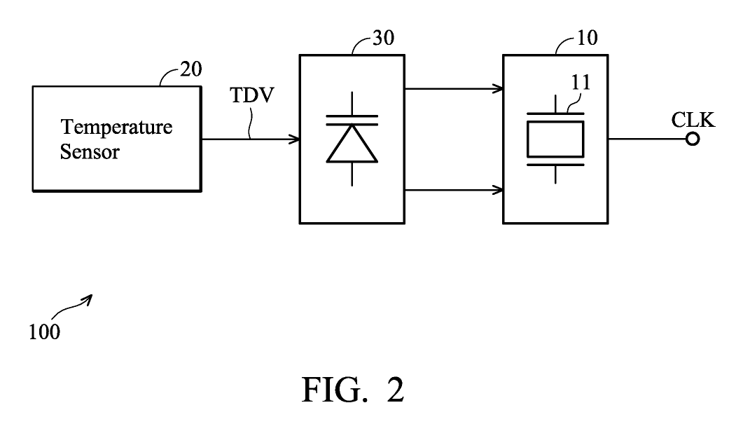

FIG. 2 is a schematic diagram of a temperature compensated oscillation circuit 100 mainly comprising a crystal oscillator 10 with a crystal resonator 11, a temperature sensor 20 and a voltage to capacitance circuit 30. The crystal oscillator 10, for example, generates an oscillation signal CLK with an output frequency by a piezo-electric effect of a crystal when being powered, and the crystal oscillator 10 can be a voltage controlled oscillator, but is not limited thereto. The temperature sensor 20 detects an ambient temperature of the crystal oscillator 10 to provide a temperature compensation voltage TDV, of which a function is linear with respect to the detected ambient temperature of the crystal oscillator 10, to the voltage to capacitance circuit 30. In some embodiments, a slope of the temperature compensation voltage with respect to the detected ambient temperature during a useable temperature interval designed for the crystal oscillator is fixed, but is not limited thereto.

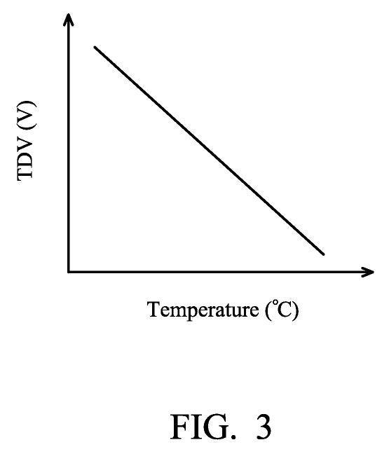

FIG. 3 shows a relationship between the temperature compensation voltage TDV and the ambient temperature. The temperature compensation voltage TDV provided by the temperature sensor 20 can be linearly decreased as the ambient temperature increases, as shown in FIG. 3, but is not limited thereto. In some examples, the temperature sensor 20 can provide a temperature compensation voltage TDV of which a function is linear with respect to the detected ambient temperature and is in direct ratio to the detected ambient temperature. Namely, the temperature compensation voltage TDV provided by the temperature sensor 20 of such examples is linearly increased as the ambient temperature increases.

The voltage to capacitance circuit 30 adjusts a capacitance thereof in response to the temperature compensation voltage TDV from the temperature sensor 20, such that the crystal oscillator 10 generates a frequency compensation of the oscillation signal CLK to compensate for the deviation of the crystal resonator over temperature. For example, the frequency compensation generated by the crystal oscillator 10 substantially varies as an inverse function of the deviation of the crystal resonator over temperature. Namely, the output frequency of the oscillation signal CLK is virtually independent from the temperature. In embodiments of the invention, the voltage to capacitance circuit 30 is implemented by one or more accumulation mode MOS varactors. In some cases, the voltage to capacitance circuit 30 can also be implemented by a combination of at least one accumulation mode MOS varactor and one or more other kind of varactors, such as P+/N well junction varactors, inversion mode MOS varactors, standard (D=S=B) MOS varactors and the like.

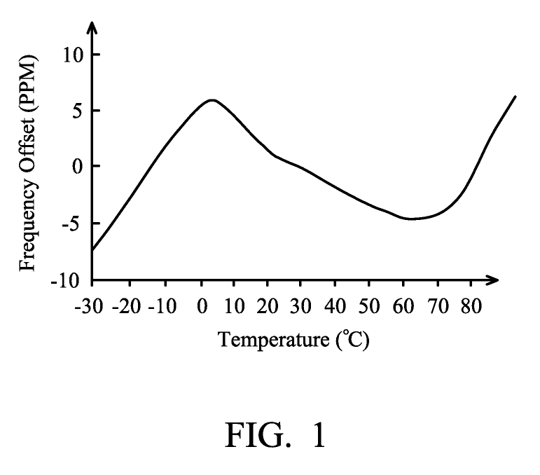

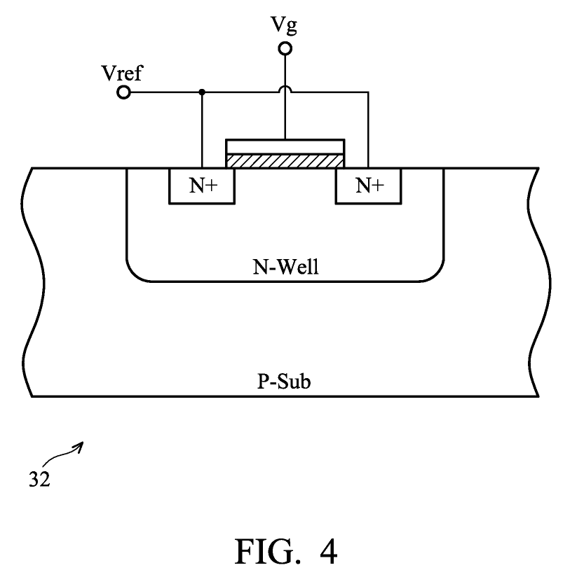

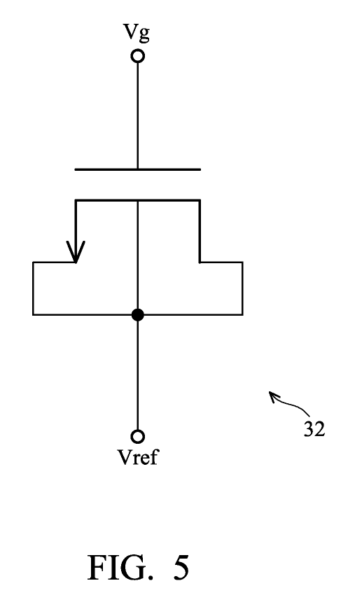

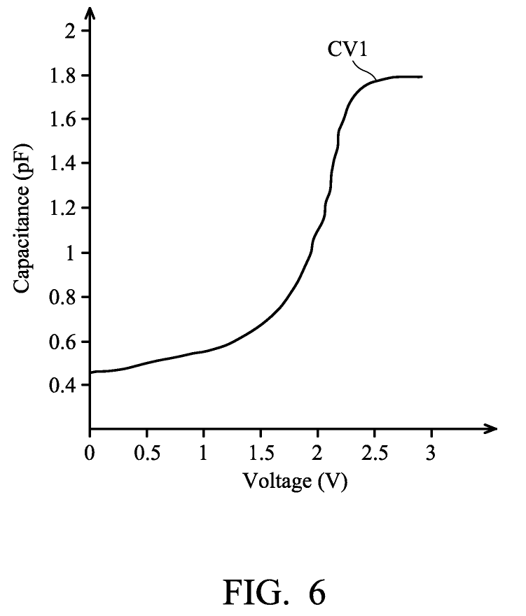

FIG. 4 shows a diagram of an accumulation mode MOS varactor according to one embodiment of the invention, and FIG. 5 shows a component symbol of the accumulation mode MOS varactor shown in FIG. 4. As shown, the accumulation mode MOS varactor 32 is implemented by an NMOS transistor in an N-well and the NMOS transistor comprises a gate coupled to a control voltage Vg, and its drain and source are coupled to a reference voltage. FIG. 6 shows a relationship between the gate-source voltage and capacitance of the accumulation mode MOS varactor according to one embodiment of the invention. As shown, curve CV1 represents the relationship between the capacitance of the accumulation mode MOS varactor 32 and the gate-source voltage. According to the slope of the curve CV1, the capacitance of the accumulation mode MOS varactor 32 is increased to about 1.8 pF from about 0.5 pF as the gate-source voltage of the accumulation mode MOS varactor 32 is increased to a relatively high voltage (3.0V) from a relatively low voltage (0.5V). With the slope of the curve CV1, being inverse to the curve representing the frequency offset of the crystal oscillator over temperature shown in FIG. 1, it is shown that the embodiments of the invention utilize the particular relationship between the capacitance and gate-source voltage of the accumulation mode MOS varactor to compensate for a deviation of the crystal resonator in the crystal oscillator over temperature.

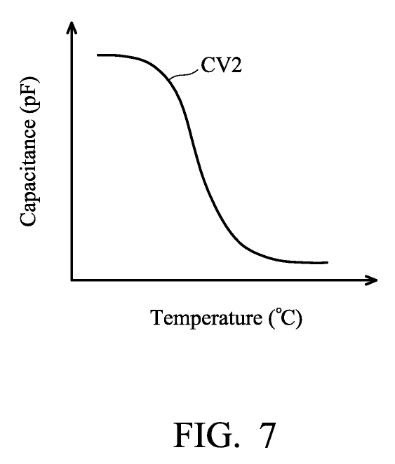

Note that assumptions include implementation of the voltage to capacitance circuit 30 by one accumulation mode MOS varactor 32 as shown in FIG. 5, the temperature detection voltage TDV serving as the control voltage Vg applied to the gate of the accumulation mode MOS varactor 32, and a fixed reference voltage Vref (i.e., the voltage coupled to the drain and source of the NMOS transistor shown in FIG. 5). Because the capacitance provided by the accumulation mode MOS varactor 32 is decreased/increased while the gate-source voltage of the accumulation mode MOS varactor 32 is decreased/increased as shown in FIG. 6 and the function of the temperature compensation voltage TDV is linear with respect to the ambient temperature and is in inverse ratio to the ambient temperature as shown in FIG. 3, the relationship between the capacitance provided by the voltage to capacitance circuit 30 (i.e., the accumulation mode MOS varactor 32) and the ambient temperature can be schematically represented as a curve CV2, as shown in FIG. 7. According to the slope of the curve CV2 in FIG. 7, the capacitance provided by the voltage to capacitance circuit 30 is decreased/increased while the ambient temperature of the crystal oscillator 10 increases/decreases. With reference to FIGS. 1 and 7, it can be obtained that, when the ambient temperature is within a temperature range, the relationship between the capacitance provided by the voltage to capacitance circuit 30 and the ambient temperature is in direct ratio to that between the frequency offset of the crystal oscillator 10 and the ambient temperature.

From

$$f = \frac{1}{2 π \sqrt{LC}} ,$$

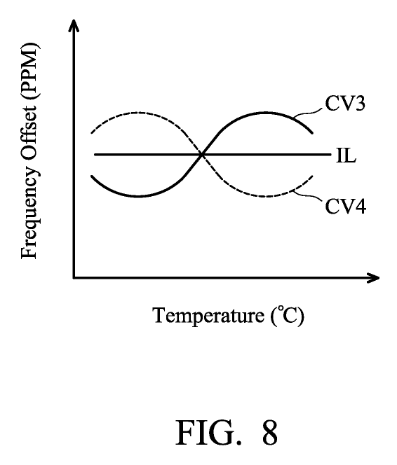

it is seen that frequency is in inverse ratio to capacitance. Hence, the relationship between the output frequency (i.e., the frequency of the oscillation signal CLK) of the crystal oscillator 10 and the ambient temperature is substantially in inverse ratio to the relationship represented by the curve CV2 in FIG. 7. As shown in FIG. 8, the curve CV3 schematically represents the relationship between the output frequency of the crystal oscillator 10 and the ambient temperature caused by the temperature compensation voltage TDV, and the curve CV4 schematically represents the deviation of the crystal resonator 11 over temperature, for example, as that of an example provided in FIG. 1. According to the slope of the curve CV3, in response to the temperature compensation voltage TDV, the output frequency of the crystal oscillator 10 increases when the capacitance provided by the voltage to capacitance circuit 30 is decreased as the ambient temperature increases. On the contrary, the output frequency of the crystal oscillator 10 decreases when the capacitance provided by the voltage to capacitance circuit 30 is increased as the ambient temperature decreases.

The curve CV4, for example, shows the deviation of the crystal resonator 11 when the ambient temperature is within a certain temperature range, but is not limited thereto. According to the slope of the curves CV3 and CV4, the variation in the output frequency of the crystal oscillator 10 caused by the voltage to capacitance circuit 30 over temperature is substantially in inverse ratio to the deviation of the crystal resonator 11 over temperature. Hence, the frequency compensation of the crystal oscillator 10 substantially varies as an inverse function of the deviation of the crystal resonator 11 over temperature when ambient temperature varies, such that the deviation caused by temperature can be compensated so that a stable frequency output IL over temperature may be provided.

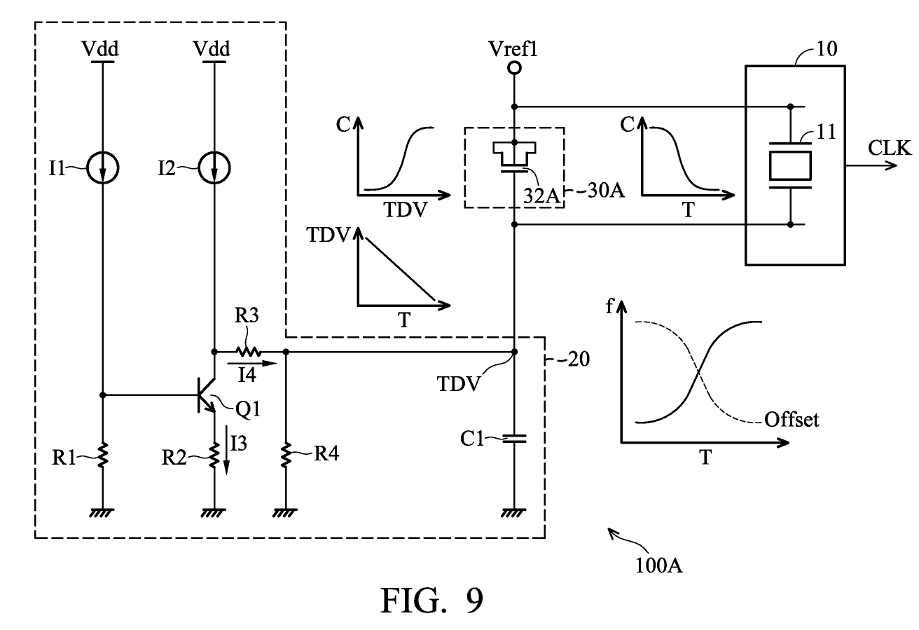

FIG. 9 shows an embodiment of the temperature compensated oscillation circuit. As shown, the crystal oscillator 10 comprises a crystal resonator 11 to generate the oscillation signal CLK, the temperature sensor 20 is implemented by current sources I1 and I2, resistors R1˜R4, a BJT transistor Q1 and a capacitor C1, and the voltage to capacitance circuit 30A is implemented by an accumulation mode MOS varactor 32A. The crystal resonator 11 comprises one terminal coupled to the gate of the accumulation mode MOS varactor 32A, and a second terminal coupled to the drain and source of the accumulation mode MOS varactor 32A. The source and drain of the accumulation mode MOS varactor 32A is coupled to a reference voltage Vref which might be a fixed voltage, and the gate of which is coupled to the temperature sensor 20 to receive the temperature detection voltage TDV.

The temperature sensor 20 detects the ambient temperature of the crystal oscillator 10 and applies the temperature detection voltage of which a function is linear with respect to the detected ambient temperature to the crystal oscillator 10 and the voltage to capacitance circuit 30A. For example, because the current sources I1 and I2 are constant current sources, the current I3 through the transistor Q1 increases and the current I4 through the resistor R3 decreases while the ambient temperature increases. Accordingly, the voltage stored at the capacitor C1 (i.e., the temperature detection voltage TDV) decreases. On the contrary, while the ambient temperature decreases, the current I3 through the transistor Q1 decreases and the current I4 through the resistor R3 increases, and the voltage stored at the capacitor C1 (i.e., the temperature detection voltage TDV) increases accordingly. Thus, the function of temperature detection voltage TDV is typically linear with respect to the detected ambient temperature and is in inverse ratio to the detected ambient temperature.

According to the relationship between the capacitance and gate-source voltage shown in FIG. 6, the accumulation mode MOS varactor 32A provides more capacitance as the temperature detection voltage TDV applied to the gate thereof increases. Hence, the accumulation mode MOS varactor 32A provides less capacitance while the ambient temperature increases as shown in FIG. 7 because the function of the temperature detection voltage TDV is linear with respect to the detected ambient temperature and is in inverse ratio to the detected ambient temperature. As frequency is in inverse ratio to capacitance, when the capacitance provided by the accumulation mode MOS varactor 32A is decreased as the ambient temperature increases, the corresponding output frequency of the crystal oscillator 10 is adjusted to have a frequency increment thereby compensating the frequency deviation caused by the temperature On the contrary, when the capacitance provided by the accumulation mode MOS varactor 32A is increased as the ambient temperature decreases, the corresponding output frequency of the crystal oscillator 10 is adjusted to have a frequency decrement thereby compensating the frequency deviation. Namely, the output frequency of the crystal oscillator 10 is adjusted along a way which is opposite to the variation in the frequency deviation of the crystal resonator 11.

As the variation in the output frequency of the crystal oscillator 10 caused by the accumulation mode MOS varactor 32A over temperature is substantially in inverse ratio to the deviation of the crystal resonator 11 over temperature, the frequency compensation of the crystal oscillator 10 varies substantially as an inverse function of the deviation of the crystal resonator 11 over temperature while ambient temperature varies. Thus, the deviation caused by temperature can be compensated by the frequency compensation so that a stable frequency output over temperature may be provided.

It should be noted that, in some embodiments, the capacitance of the accumulation mode MOS varactor varies merely when the gate-source voltage of which varies within a predetermined voltage range. For example, as shown in FIG. 6, the capacitance is maintained at about 1.8 pF when the gate-source of the accumulation mode MOS varactor 32 exceeds 3.0V, and the capacitance is maintained at about 0.7 pF when the gate-source of the accumulation mode MOS varactor 32 is lower than 0.5V. Namely, because the temperature detection voltage TDV is linear with respect to the detected ambient temperature, the capacitance of the accumulation mode MOS varactor 32A in FIG. 9 varies to compensate for the deviation of the crystal resonator 11 when the ambient temperature is within a predetermined range. For example, the accumulation mode MOS varactor 32A can adjust the capacitance thereof to compensate for the deviation of the crystal resonator 11 when the detected ambient temperature is between the predetermined temperature range, but is not limited thereto. In some examples, the predetermined temperature range can be within about 0° C. and 50° C., but is not limited thereto.

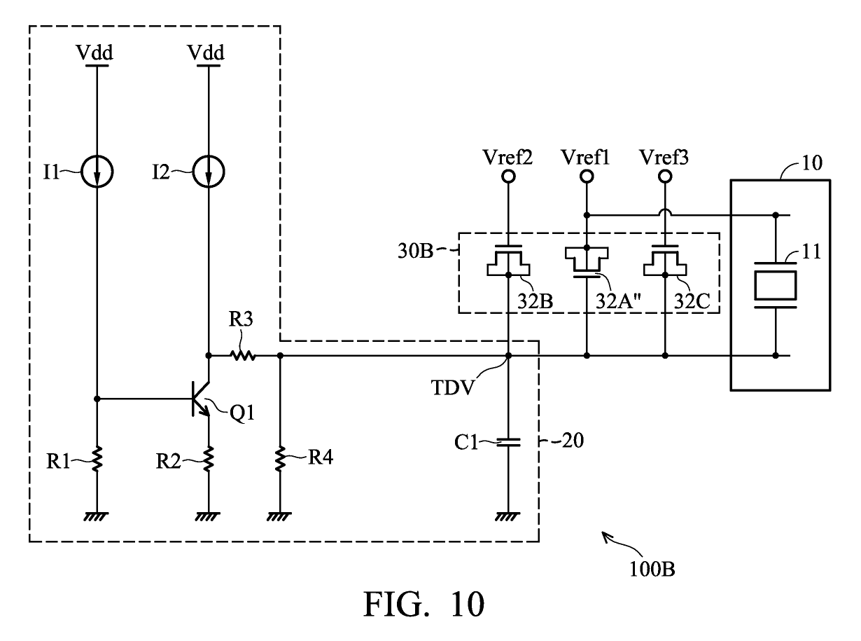

FIG. 10 shows another embodiment of the temperature compensated oscillation circuit. In order to compensate the frequency deviation in a temperature range wider than that for the temperature compensated oscillation circuit 100A, three accumulation mode MOS varactors 32A″, 32B and 32C are employed in the temperature compensated oscillation circuit 100B. As shown, the temperature compensated oscillation circuit 100B is similar to the temperature compensated oscillation circuit 100A in FIG. 9, differing only, in that the voltage to capacitance circuit 30B is implemented by three accumulation mode MOS varactors 32A″, 32B and 32C. The similar structures and operations with respect to the temperature compensated oscillation circuit 100A are omitted for brevity. For example, the temperature compensated oscillation circuit 100B can also be operated to compensate the frequency deviation even if the detected ambient temperature is below 0° C. or is higher than 50° C. In some examples, the temperature compensated oscillation circuit 100B can be operated when the detected ambient temperature is within about −20° C. and 80° C., but is not limited thereto.

The source and drain of the accumulation mode MOS varactor 32A″ is coupled to the reference voltage Vref1, and the temperature detection voltage TDV is applied to the gate of the accumulation mode MOS varactor 32A″. As set fourth, the accumulation mode MOS varactor 32A″ can only adjust the capacitance thereof when the gate voltage (i.e., the temperature detection voltage TDV) is within a predetermined voltage range. For example, the accumulation mode MOS varactor 32A″ adjusts the capacitance thereof when the temperature detection voltage TDV is between V1 and V2.

In this embodiment, when the temperature detection voltage TDV is lower than V1 or higher than V2, the capacitance of the accumulation mode MOS varactor 32A″ is maintained and the voltage to capacitance circuit 30B adjusts the capacitance thereof by the accumulation mode MOS varactors 32B or 32C. The accumulation mode MOS varactors 32A″ and 32B are connected in parallel with inverse direction. Namely, the gate of the accumulation mode MOS varactor 32B is coupled to a reference voltage Vref2, and the temperature detection voltage TDV is applied to drains and sources of the accumulation mode MOS varactor 32B. Because the accumulation mode MOS varactors 32A″ and 32B are connected in parallel with inverse direction, the relationship of the tuning slope between capacitance and the gate-source voltage of the accumulation mode MOS varactor 32B is in inverse to that of the accumulation mode MOS varactor 32A″. Hence, by selecting an appropriate fixed voltage to serve as the reference voltage Vref2, the capacitance provided by the accumulation mode MOS varactor 32B increases as the temperature detection voltage TDV decreases when the temperature detection voltage TDV is lower then V1.

Similarly, the accumulation mode MOS varactors 32A″ and 32C are connected in parallel with inverse direction. Namely, the gate of the accumulation mode MOS varactor 32C is coupled to a reference voltage Vref3, and the temperature detection voltage TDV is applied to drains and sources of the accumulation mode MOS varactor 32C. The relationship between capacitance and gate-source voltage of the accumulation mode MOS varactor 32C is inverse to that of the accumulation mode MOS varactor 32A″, because the accumulation mode MOS varactors 32A″ and 32C are connected in parallel with inverse direction. Hence, by selecting an appropriate fixed voltage to serve as the reference voltage Vref3, the capacitance provided by the accumulation mode MOS varactor 32C decreases as the temperature detection voltage TDV increases when the temperature detection voltage TDV is higher then V2.

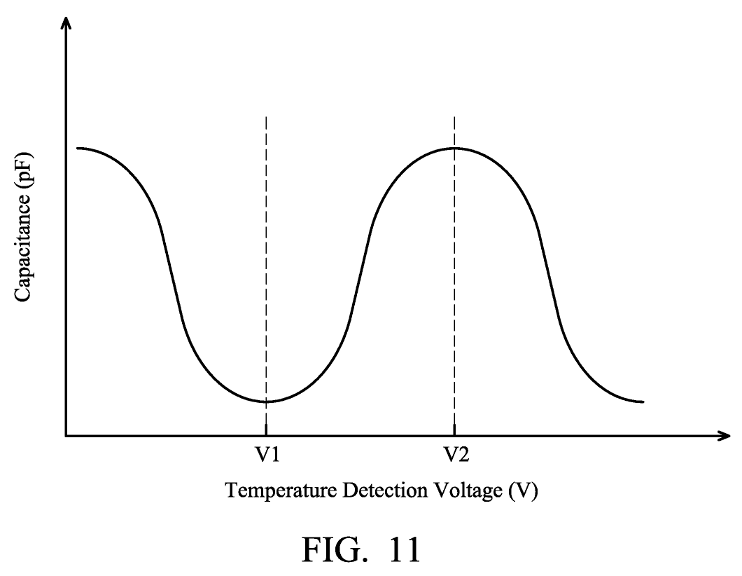

Namely, if the reference voltages Vref1˜Vref3 are appropriate, the capacitances provided by the accumulation mode MOS varactors 32A″ and 32C are almost maintained and the total capacitance provided by the voltage to capacitance circuit 30B is mainly adjusted by the accumulation mode MOS varactor 32B when the temperature detection voltage TDV is lower than V1. When the temperature detection voltage TDV is between V1 and V2, the capacitances provided by the accumulation mode MOS varactors 32B and 32C are almost maintained and the total capacitance provided by the voltage to capacitance circuit 30B is mainly adjusted by the accumulation mode MOS varactor 32A″. When the temperature detection voltage TDV is higher than V2, the capacitances provided by the accumulation mode MOS varactors 32A″ and 32B are almost maintained and the total capacitance provided by the voltage to capacitance circuit 30B is mainly adjusted by the accumulation mode MOS varactor 32C. The relationship between the capacitance provided by the voltage to capacitance circuit 30B and the temperature detection voltage TDV is shown in FIG. 11. For example, the reference voltages Vref1˜Vref3 are different, but is not limited thereto.

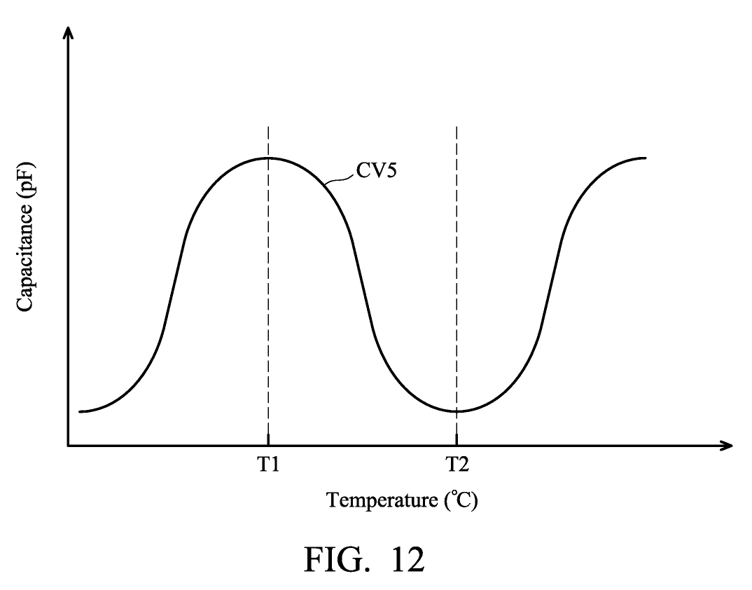

Because the function of the temperature detection voltage TDV is linear with respect to the detected ambient temperature and is in inverse ratio to the detected ambient temperature, the relationship between the capacitance provided by the voltage to capacitance circuit 30B and the temperature can be represented as a curve CV5 as shown in FIG. 12. It should be noted that the temperatures T1 and T2 are corresponding to the voltages V1 and V2 shown in FIG. 11. Hence, when the detected ambient temperature is between T1 and T2, the capacitance provided by the voltage to capacitance circuit 30B is mainly adjusted by the accumulation mode MOS varactor 32A″. When the detected ambient temperature is lower T1, the capacitance provided by the voltage to capacitance circuit 30B is mainly adjusted by the accumulation mode MOS varactor 32B. When the detected ambient temperature is higher than T2, the capacitance provided by the voltage to capacitance circuit 30B is mainly adjusted by the accumulation mode MOS varactor 32C.

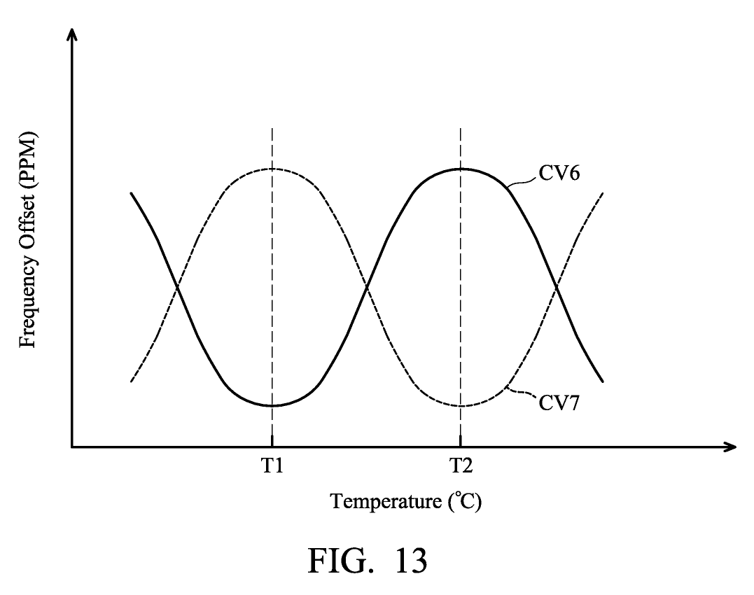

As the frequency is in inverse ratio to the capacitance, the relationship between the output frequency of the crystal oscillator 10 and the ambient temperature is substantially in inverse ratio to the relationship represented by the curve CV5 shown in FIG. 13. As shown, the curve CV6 schematically represents the relationship between the output frequency of the crystal oscillator 10 and the ambient temperature caused by the temperature compensation voltage TDV, and the curve CV7 schematically represents the deviation of the crystal resonator 11 over temperature. According to the slope of the curves CV6 and CV7, the variation in the output frequency of the crystal oscillator 10 caused by the voltage to capacitance circuit 30B over temperature is substantially in inverse ratio to the deviation of the crystal resonator 11 over temperature. Namely, the frequency compensation of the crystal oscillator 10 substantially varies as an inverse function of the deviation of the crystal resonator 11 over temperature when ambient temperature varies, such that the deviation caused by temperature can be compensated so that a stable frequency output over temperature may be provided.

In some examples, one of the accumulation mode MOS varactors 32B and 32C can be replaced by a P+/N well junction varactor, or both the accumulation mode MOS varactors 32B and 32C can be replaced by two P+/N well junction varactors, but is not limited thereto. The accumulation mode MOS varactors 32B and 32C can also be replaced by inversion mode MOS varactors, standard (D=S=B) MOS varactors or a combination thereof.

Certain terms are used throughout the description and claims to refer to particular system components. As one skilled in the art will appreciate, consumer electronic equipment manufacturers may refer to a component by different names. This document does not intend to distinguish between components that differ in name but not function.

Although the invention has been described in terms of preferred embodiment, it is not limited thereto. Those skilled in the art can make various alterations and modifications without departing from the scope and spirit of the invention. Therefore, the scope of the invention shall be defined and protected by the following claims and their equivalents.

What is claimed is:

1. A temperature compensated oscillation circuit, comprising:
an oscillator comprising a crystal resonator, wherein the oscillator is arranged to generate an oscillation signal with an output frequency;
a temperature sensor, for providing a temperature compensation voltage of which a function is linear with respect to an ambient temperature of the oscillator; and
a first accumulation mode MOS varactor coupled to the oscillator, in response to the temperature compensation voltage, the first accumulation mode MOS varactor adjusting a capacitance thereof, such that the coupled oscillator has a frequency compensation over temperature for the oscillation signal, wherein the frequency compensation substantially varies as an inverse function of a deviation of the crystal resonator over temperature when the ambient temperature is within a predetermined temperature range.

2. The temperature compensated oscillation circuit as claimed in claim 1, further comprising a P+/N well junction varactor for adjusting a capacitance thereof in response to the temperature compensation voltage, such that the frequency compensation over temperature substantially varies as the inverse function of the deviation of the crystal resonator when the ambient temperature is not within the predetermined temperature range.

3. The temperature compensated oscillation circuit as claimed in claim 1, wherein the first accumulation mode MOS varactor comprises a gate receiving the temperature compensation voltage and a drain and a source both coupled to a first reference voltage, and the temperature compensated oscillation circuit further comprises a second accumulation mode MOS varactor for adjusting a capacitance thereof in response to the temperature compensation voltage, such that the frequency compensation over temperature substantially varies as the inverse function of the deviation of the crystal resonator when the ambient temperature is not within the predetermined temperature range.

4. The temperature compensated oscillation circuit as claimed in claim 1, wherein, when the ambient temperature is within the predetermined temperature range, a function of the capacitance of the first accumulation mode MOS varactor over temperature substantially varies in direct ratio to the deviation of the crystal resonator in response to the temperature compensation voltage.

5. The temperature compensated oscillation circuit as claimed in claim 2, wherein, when the ambient temperature is not within the predetermined temperature range, a function of the capacitance of the P+/N well junction varactor over temperature substantially varies in direct ratio to the deviation of the crystal resonator in response to the temperature compensation voltage.

6. The temperature compensated oscillation circuit as claimed in claim 3, wherein, when the ambient temperature is not within the predetermined temperature range, a function of the capacitance of the second accumulation mode MOS varactor over temperature substantially varies in direct ratio to the deviation of the crystal resonator in response to the temperature compensation voltage.

7. The temperature compensated oscillation circuit as claimed in claim 1, wherein the oscillator is a voltage controlled oscillator { [symbol] [0020]}.

8. A temperature compensated oscillation circuit, comprising:
a crystal oscillator providing an oscillation signal with an output frequency;
a temperature sensor, for detecting an ambient temperature of the crystal oscillator and providing a temperature compensation voltage which is linear with respect to a detected ambient temperature; and
a first accumulation mode MOS varactor coupled to the crystal oscillator, for receiving the temperature compensation voltage provided by the temperature sensor to compensate the output frequency of the oscillation signal when the detected ambient temperature is within a predetermined temperature range.

9. The temperature compensated oscillation circuit as claimed in claim 8, further comprising an auxiliary varactor coupled to the crystal oscillator, for receiving the temperature compensation voltage to compensate the output frequency of the crystal oscillator when the detected ambient temperature is outside the predetermined temperature range.

10. The temperature compensated oscillation circuit as claimed in claim 9, wherein the auxiliary varactor is a P+/N well junction varactor or a second accumulation mode MOS varactor.

11. The temperature compensated oscillation circuit as claimed in claim 10, wherein the first accumulation mode MOS varactor comprises a gate coupled to the temperature compensation voltage and a drain and a source both coupled to a first reference voltage, the second accumulation mode MOS varactor comprises a gate coupled to a second reference voltage and a drain and a source both coupled to the temperature compensation voltage, in which the first and second reference voltages are different.

12. A method for compensating frequency offset over temperature of a crystal oscillator, comprising:
detecting an ambient temperature of an oscillator having a crystal resonator to provide a temperature compensation voltage of which a function is linear with respect to the detected ambient temperature, wherein the oscillator is arranged to generate an oscillation signal with an output frequency; and
applying the temperature compensation voltage to a first accumulation mode MOS varactor coupled to the oscillator to adjust a capacitance provided by the first accumulation mode MOS varactor, such that the oscillator has a frequency compensation over temperature for the oscillation signal, wherein the frequency compensation substantially varies as an inverse function of a deviation of the crystal resonator over temperature when the detected ambient temperature is within a predetermined temperature range.

13. The method as claimed in claim 12, further comprising applying the temperature compensation voltage to an auxiliary varactor coupled to the oscillator to adjust a capacitance provided by the auxiliary varactor, such that the frequency compensation substantially varies as the inverse function of the deviation of the crystal resonator when the ambient temperature is outside the predetermined temperature range.

14. The method as claimed in claim 12, wherein, when the ambient temperature is within the predetermined temperature range, a function of the capacitance of the accumulation mode MOS varactor over temperature substantially varies in direct ratio to the deviation of the crystal resonator in response to the temperature compensation voltage, thereby adjusting the frequency compensation over temperature to vary substantially as the inverse function of the deviation of the crystal resonator.

15. The method as claimed in claim 13, wherein, when the ambient temperature is not within the predetermined temperature range, the function the capacitance of the auxiliary varactor substantially varies in direct ratio to the deviation of the crystal resonator over temperature in response to the temperature compensation voltage, thereby adjusting the frequency compensation to vary substantially as the inverse function of the deviation of the crystal resonator.
